(19) United States
(12) Patent Application Publication
(10) Pub. No.: US 2025/0089442 A1
(43) Pub. Date: Mar. 13, 2025

(54) DISPLAY PANEL AND DISPLAY APPARATUS

(71) Applicant: BOE TECHNOLOGY GROUP CO., LTD., Beijing (CN)

(72) Inventors: Linlin Wang, Beijing (CN); Dandan Zhou, Beijing (CN); Cheng Xu, Beijing (CN)

(21) Appl. No.: 18/548,328

(22) PCT Filed: Nov. 29, 2022
(86) PCT No.: PCT/CN2022/135092

§ 371 Date: Aug. 29, 2023

(51) Int. Cl. H10K 50/13; H10K 50/852; H10K 59/38; H10K 102/00

(52) U.S. Cl. CPC H10K 50/13; H10K 50/852; H10K 59/38; H10K 2102/331; H10K 2102/351

(57) ABSTRACT

A display panel is provided, including light emitting devices arranged in an array, and each light emitting devices includes: a first electrode; a first light emitting layer, a second light emitting layer, a third light emitting layer, a fourth light emitting layer, a fifth light emitting layer, and a second electrode, which are all arranged sequentially. A microcavity is formed between the first electrode and the second electrode, four light emitting layers among the first light emitting layer, the second light emitting layer, the third light emitting layer, the fourth light emitting layer and the fifth light emitting layer emit light having a first wavelength, and a remaining light emitting layer, except for the four light emitting layers emitting the light having the first wavelength, emits light having a second wavelength. The first wavelength is smaller than the second wavelength.

### CROSS-REFERENCE TO RELATED APPLICATION

This application is a Section 371 National Stage Application of International Application No. PCT/CN2022/135092, filed Nov. 29, 2022, entitled “DISPLAY PANEL AND DISPLAY APPARATUS”, which is incorporated herein by reference in its entirety.

### TECHNICAL FIELD

The present disclosure relates to a field of display technology, and in particular, to a display panel and a display apparatus.

### BACKGROUND

Organic Light-Emitting Diodes (OLEDs) attract great attention and are increasingly applied to various types of display apparatus in recent years due to advantages of simple preparation process, low cost, and realizing flexible display. With the application and promotion of OLEDs, Quantum Dots (QDs) have also been applied to display apparatus containing OLED due to their luminescent properties. Although the current QD-OLED (Quantum Dot Organic Light-Emitting Diode) products have advantages such as high color gamut, high color purity, and no perspective dependence, they still have problems of high power consumption and short lifespan.

The above information disclosed in this section is only for an understanding of the background of the inventive concept of the present disclosure, and therefore, the above information may contain information that does not constitute the prior art.

### SUMMARY

In order to solve at least one aspect of the above-mentioned problems, embodiments of the present disclosure provides a display panel and a display apparatus.

In one aspect, there is provided a display panel, including a plurality of light emitting devices arranged in an array, where each of the plurality of light emitting devices includes: a first electrode; a first light emitting layer on the first electrode; a second light emitting layer on a side of the first light emitting layer away from the first electrode; a third light emitting layer on a side of the second light emitting layer away from the first electrode; a fourth light emitting layer on a side of the third light emitting layer away from the first electrode; a fifth light emitting layer on a side of the fourth light emitting layer away from the first electrode; and a second electrode on a side of the fifth light emitting layer away from the first electrode, where a microcavity is formed between the first electrode and the second electrode, four light emitting layers among the first light emitting layer, the second light emitting layer, the third light emitting layer, the fourth light emitting layer and the fifth light emitting layer emit light of a first wavelength, a remaining light emitting layer, except for the four light emitting layers emitting light having the first wavelength, among the first light emitting layer, the second light emitting layer, the third light emitting layer, the fourth light emitting layer and the fifth light emitting layer emits light having a second wavelength, and the first wavelength is smaller than the second wavelength.

According to some exemplary embodiments, the light having the first wavelength emitted by the four light emitting layers forms a first standing wave in the light emitting device, and the light having the second wavelength emitted by the remaining light emitting layer forms a second standing wave in the light emitting device.

According to some exemplary embodiments, a first distance from a first surface of the first electrode close to the first light emitting layer to a surface of the first light emitting layer on a side away from the first electrode is less than 500 Å.

According to some exemplary embodiments, the second light emitting layer, the third light emitting layer, the fourth light emitting layer and the fifth light emitting layer emit blue light, and the first light emitting layer emits green light.

According to some exemplary embodiments, a surface of the first electrode facing the first light emitting layer serves as a reference surface, the second light emitting layer is located at a second antinode of the first standing wave, the third light emitting layer is located at a third antinode of the first standing wave, the fourth light emitting layer is located at a fourth antinode of the first standing wave, the fifth light emitting layer is located at a fifth antinode of the first standing wave, and the first light emitting layer is located at a first antinode of the second standing wave.

According to some exemplary embodiments, the first light emitting layer, the third light emitting layer, the fourth light emitting layer, and the fifth light emitting layer emit blue light, and the second light emitting layer emits green light.

According to some exemplary embodiments, a surface of the first electrode facing the first light emitting layer serves as a reference surface, the first light emitting layer is located at a first antinode of the first standing wave, the third light emitting layer is located at a third antinode of the first standing wave, the fourth light emitting layer is located at a fourth antinode of the first standing wave, the fifth light emitting layer is located at a fifth antinode of the first standing wave, and the second light emitting layer is located at a second antinode of the second standing wave.

According to some exemplary embodiments, the first light emitting layer, the second light emitting layer, the third light emitting layer, and the fifth light emitting layer emit blue light, and the fourth light emitting layer emits green light.

According to some exemplary embodiments, a surface of the first electrode facing the first light emitting layer serves as a reference surface, the first light emitting layer is located at a first antinode of the first standing wave, the second light emitting layer is located at a second antinode of the first standing wave, and the third light emitting layer is located at a third antinode of the first standing wave, the fifth light emitting layer is located at a fifth antinode of the first standing wave, and the fourth light emitting layer is located at a third antinode of the second standing wave.

According to some exemplary embodiments, the first light emitting layer, the second light emitting layer, the third light emitting layer, and the fourth light emitting layer emit blue light, and the fifth light emitting layer emits green light.

According to some exemplary embodiments, a surface of the first electrode facing the first light emitting layer serves as a reference surface, the first light emitting layer is located at a first antinode of the first standing wave, the second light emitting layer is located at a second antinode of the first standing wave, and the third light emitting layer is located at a third antinode of the first standing wave, the fourth light emitting layer is located at a fourth antinode of the first standing wave, and the fifth light emitting layer is located at a fourth antinode of the second standing wave.

According to some exemplary embodiments, a second distance between the first electrode and the second electrode is equal to 5 times a distance between two adjacent antinodes of the first standing wave or 4 times a distance between two adjacent antinodes of the second standing wave.

According to some exemplary embodiments, a first distance from a first surface of the first electrode close to the first light emitting layer to a surface of the first light emitting layer on a side away from the first electrode is greater than 1200 Å.

According to some exemplary embodiments, the second light emitting layer, the third light emitting layer, the fourth light emitting layer, and the fifth light emitting layer emit blue light, and the first light emitting layer emits green light.

According to some exemplary embodiments, a surface of the first electrode facing the first light emitting layer serves as a reference surface, the second light emitting layer is located at a third antinode of the first standing wave, the third light emitting layer is located at a fourth antinode of the first standing wave, the fourth light emitting layer is located at a fifth antinode of the first standing wave, the fifth light emitting layer is located at a sixth antinode of the first standing wave, and the first light emitting layer is located at a second antinode of the second standing wave.

According to some exemplary embodiments, a second distance between the first electrode and the second electrode is equal to 6 times a distance between two adjacent antinodes of the first standing wave or 5 times a distance between two adjacent antinodes of the second standing wave.

According to some exemplary embodiments, each of the four light emitting layers emitting light having the first wavelength in the first light emitting layer, the second light emitting layer, the third light emitting layer, the fourth light emitting layer, and the fifth light emitting layer has a thickness in a range of 200 Å to 250 Å, and the light emitting layer emitting light having the second wavelength in the first light emitting layer, the second light emitting layer, the third light emitting layer, the fourth light emitting layer, and the fifth light emitting layer has a thickness in a range of 300 Å to 350 Å.

According to some exemplary embodiments, each of the plurality of light emitting devices further includes a first charge generating layer between the first light emitting layer and the second light emitting layer, a second charge generating layer between the second light emitting layer and the third light emitting layer, a third charge generating layer between the third light emitting layer and the fourth light emitting layer, and a fourth charge generating layer between the fourth light emitting layer and the fifth light emitting layer.

According to some exemplary embodiments, at least one light emitting layer in the plurality of light emitting devices includes one or two layers of a hole injection layer and a hole transport layer on a side close to the first electrode, and one or two layers of an electron transport layer and an electron injection layer away from the first electrode.

According to some exemplary embodiments, the display panel further includes a wavelength conversion layer on a side of the second electrode away from the first electrode, where a material of the wavelength conversion layer includes quantum dots.

In another aspect, there is provided a display apparatus, including the display panel described above.

### BRIEF DESCRIPTION OF THE DRAWINGS

Other objectives and advantages of the present disclosure will become more apparent through the following description of the present disclosure with reference to the accompanying drawings, which may assist in a comprehensive understanding of the present disclosure.

FIG. 1A schematically shows a top view of a display panel according to an embodiment of the present disclosure.

FIG. 1B schematically shows a sectional view of a light emitting device taken along A-A′ line in FIG. 1A according to an embodiment of the present disclosure.

FIG. 1C schematically shows a relationship between a cavity length thickness and an emission spectrum of a light emitting device according to an embodiment of the present disclosure.

FIG. 1D schematically shows a schematic diagram of a standing wave and an antinode according to an embodiment of the present disclosure.

FIG. 1E schematically shows a spectrogram of light emitted by a light emitting device according to an embodiment of the present disclosure, where a first light emitting layer of the light emitting device emits green light.

FIG. 2A schematically shows a sectional view of a light emitting device according to another embodiment of the present disclosure.

FIG. 2B schematically shows a spectrogram of light emitted by a light emitting device according to an embodiment of the present disclosure, where a second light emitting layer of the light emitting device emits green light.

FIG. 3A schematically shows a sectional view of a light emitting device according to another embodiment of the present disclosure.

FIG. 3B schematically shows a spectrogram of light emitted by a light emitting device according to an embodiment of the present disclosure, where a fourth light emitting layer of the light emitting device emits green light.

FIG. 4A schematically shows a sectional view of a light emitting device according to another embodiment of the present disclosure.

FIG. 4B schematically shows a spectrogram of light emitted by a light emitting device according to an embodiment of the present disclosure, where a fifth light emitting layer of the light emitting device emits green light.

FIG. 5A schematically shows a sectional view of a light emitting device according to another embodiment of the present disclosure.

FIG. 5B schematically shows a spectrogram of light emitted by a light emitting device according to an embodiment of the present disclosure, where a second distance is greater than 1200 Å.

It should be noted that, for the sake of clarity, dimensions of layers, structures or regions in the accompanying drawings used to describe embodiments of the present disclosure may be exaggerated or reduced, i.e., the accompanying drawings are not drawn to an actual scale.

### DETAILED DESCRIPTION OF EMBODIMENTS

The technical solution of the present disclosure is further specifically described below through embodiments and in combination with the accompanying drawings. In the specification, the same or similar reference signs denote the same or similar parts. The following description of embodiments of the present disclosure with reference to the accompanying drawings is intended to explain the general inventive concept of the present disclosure, and should not be construed as limiting the present disclosure.

In addition, in the following detailed descriptions, for ease of explanation, numerous specific details are set forth in order to provide a thorough understanding of embodiments of the present disclosure. However, it is obvious that one or more embodiments may be implemented without these specific details.

It should be understood that, although the terms first, second, etc. may be used herein to describe various elements, these elements should not be limited by these terms. These terms are only used to distinguish one element from another. For example, without departing from the scope of example embodiments, a first element could be termed a second element, and, similarly, a second element could be termed a first element. As used herein, a term “and/or” includes any and all combinations of one or more of related items listed.

It should be understood that when an element or layer is described as being “formed on” another element or layer, the element or layer may be directly or indirectly formed on the another element or layer. That is, for example, there may be an intervening element or an intervening layer. On the contrary, when an element or layer is described as being “directly formed on” another element or layer, there is no intervening element or intervening layer. Other terms used to describe a relationship between elements or layers should be interpreted in a similar way, such as, “between . . . and” versus “directly between . . . and”, “adjacent” versus “directly adjacent”, etc.

Herein, unless otherwise specifically stated, the expression “on a same layer” generally means that a first part and a second part may be made of a same material and formed by using a same patterning process. The expression “A and B are connected as a whole” means that a part A and a part B are formed as an integral structure, that is, the part A and the part B generally contain a same material and are formed as a structurally continuous integral part.

In present disclosure, unless otherwise specified, directional terms such as “up”, “down”, “left”, “right”, “inside”, and “outside” are used to indicate orientations or positional relationships shown based on the drawings, merely for convenience of describing the present disclosure, rather than indicating or implying that the devices, elements, or components referred to must have a particular orientation, be constructed or operated in a particular orientation. It should be understood that when the absolute positions of the described objects change, relative positional relationships they represent may also change accordingly. Accordingly, these directional terms should not be construed as limiting the present disclosure.

In present disclosure, expressions “vertical”, “vertical connection”, or similar expressions not only include a case of 90 degrees, i.e., a case of being completely vertical, but also include a case of a deviation from 90 degrees within a certain error range, such as a case of a deviation from 90 degrees within a process error range.

The potential advantages of QD-OLED lie in its high resolution, high color gamut, high color purity, and no perspective dependence. In addition, there are potential application advantages, for example, they are applicable to large/high-color-gamut products, or medium UHD (Ultra High Definition) products which have high value. Although the current QD-OLED products have advantages such as high color gamut, high color purity, and no perspective dependence, they still have problems of high power consumption and short lifespan.

In view of the above, the inventors of the present disclosure find that a combination of QD-OLED and EL (light-emitting layer) microcavity structure may further improve the light emission efficiency and color purity. Although there may be a problem of perspective dependence, the provision of QD may solve the problem of perspective dependence, and an appropriate integration solution may also be used to ensure the optimization of optical effects. Red and green pixels on a color conversion layer composed of quantum dot materials do not provide a strong optical modulation effect, after they absorb blue light OLED and emit light, only light color conversion is performed, and the perspective characteristics still conform to the traditional Lambert distribution.

In order to reduce a power consumption of a light emitting device, blue light OLED adopts a structure with strong optical resonator function. The blue light OLED has emission spectrum with a narrow half-wave-width, so as to improve the emission intensity of blue light (the blue pixel with high emission intensity may reduce the power consumption of the light emitting device) and the color purity of the blue light. In addition, the blue light having high emission intensity and concentrating in a wavelength range for exciting a specific red/green quantum dot may improve emission intensity of the red/green pixel, and the improved emission intensity of the red/green pixel may reduce the power consumption of the light emitting device. Therefore, the structure with strong optical resonator function is necessary in a process of reducing the power consumption of the light emitting device. In order to obtain red and green light with a high brightness, the blue light used for excitation is required to have a high brightness, and the goodness of fit of blue light device and QD device is very important. Therefore, the research on the structure of light emitting device for reducing power consumption is a top priority.

Based on this, embodiments of the present disclosure provide a light emitting device having five stacked layers inside. By calculating a power consumption color gamut, it may be concluded that when the number of stacked layers of light emitting layers in the light emitting device is five, the power consumption of the light emitting device is low, and the reduction of power consumption also contributes to extension of the lifespan.

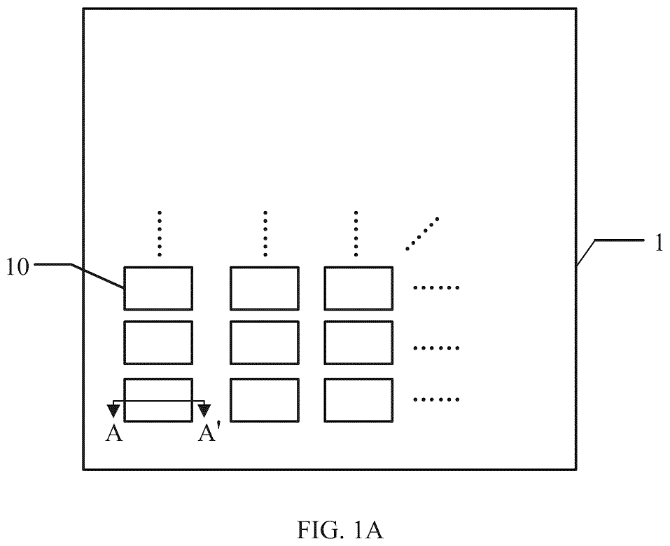

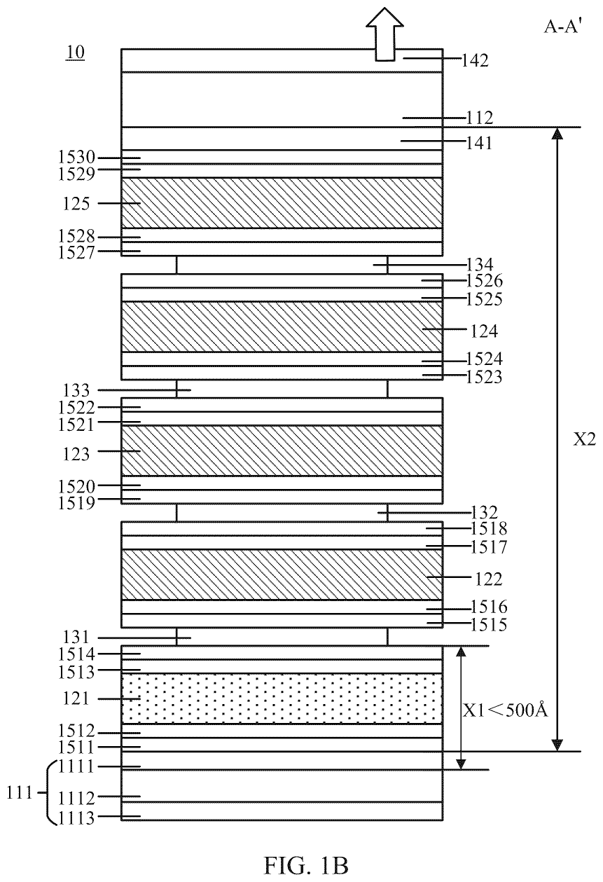

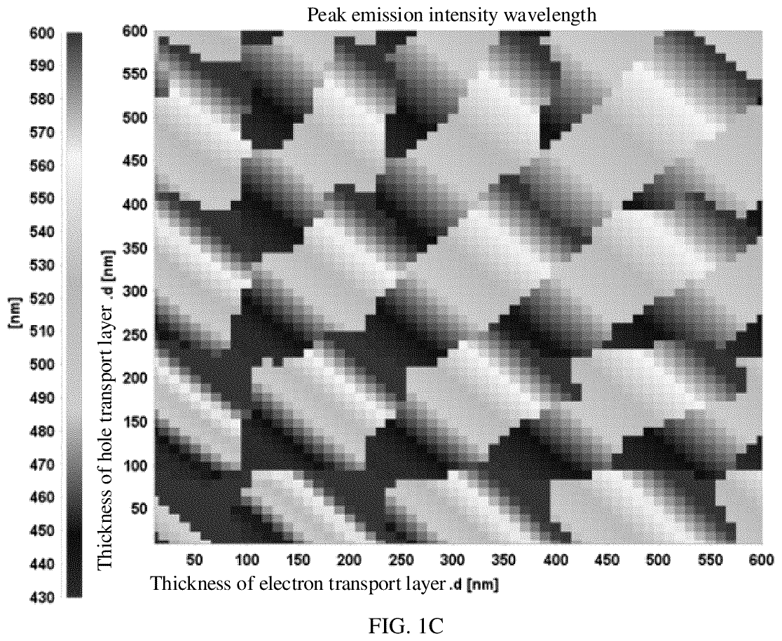

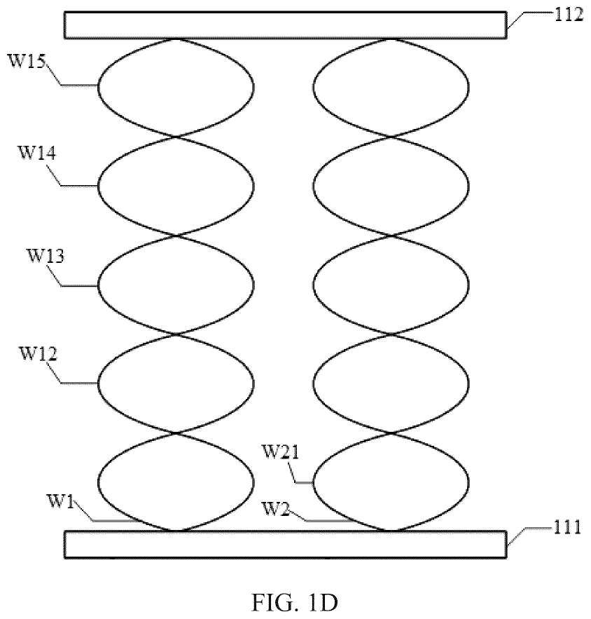

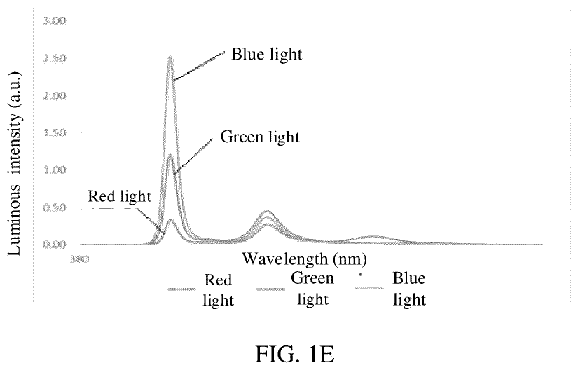

FIG. 1A schematically shows a top view of a display panel according to an embodiment of the present disclosure. FIG. 1B schematically shows a sectional view of a light emitting device taken along A-A′ line in FIG. 1A according to an embodiment of the present disclosure.

As shown in FIG. 1A to FIG. 1B, a display panel includes a plurality of light emitting devices arranged in an array, and a light emitting device 10 includes: a first electrode 111; a first light emitting layer 121 on the first electrode 111; a second light emitting layer 122 on a side of the first light emitting layer 121 away from the first electrode 111; a third light emitting layer 123 on a side of the second light emitting layer 122 away from the first electrode 111; a fourth light emitting layer 124 on a side of the third light emitting layer 123 away from the first electrode 111; a fifth light emitting layer 125 on a side of the fourth light emitting layer 124 away from the first electrode 111; and a second electrode 112 on a side of the fifth light emitting layer 125 away from the first electrode 111. A microcavity is formed between the first electrode 111 and the second electrode 112. Four light emitting layers among the first light emitting layer 121, the second light emitting layer 122, the third light emitting layer 123, the fourth light emitting layer 124 and the fifth light emitting layer 125 emit light having a first wavelength, and a remaining light emitting layer, except for the four light emitting layers emitting the light having the first wavelength, among the first light emitting layer 121, the second light emitting layer 122, the third light emitting layer 123, the fourth light emitting layer 124 and the fifth light emitting layer 125 emits light having a second wavelength, where the first wavelength is smaller than the second wavelength.

According to the embodiments of the present disclosure, the power consumption of the light emitting device is associated with the number of stacked layers of the light emitting layers in the light emitting device, and selecting an appropriate number of the stacked layers is conducive to the reduction of the power consumption of the light emitting device. By calculating the power consumption color gamut, when the number of the stacked layers of the light emitting layers in the light emitting device is five, the power consumption of the light emitting device is low. Accordingly, in the embodiments of the present disclosure, five light emitting layers 121, 122, 123, 124 and 125 stacked sequentially are arranged in each light emitting device 10, thereby contributing to the reduction of the power consumption of the light emitting device 10. Further, compared with five light emitting layers all emitting light having the first wavelength, by configuring the four light emitting layers among the five light emitting layers 121, 122, 123, 124 and 125 to emit light having the first wavelength and the remaining one light emitting layer emits light having the second wavelength, when it is expected to obtain the light having the second wavelength through the light emitting device 10, the light having the first wavelength emitted by the light emitting device 10 may be converted into the light having the second wavelength, and the converted light having the second wavelength is superimposed with the light having the second wavelength emitted by the light emitting device 10 as the finally obtained light having the second wavelength. In this way, not only the requirements for high luminous and high intensity of the emission light by the light emitting device 10 may be realized by using the characteristics of the spectrum of the light having the first wavelength with the narrow half-wave width, but also the light having the second wavelength emitted by the light emitting device 10 itself may be used as a supplementary light source, so that a total amount of the obtained light having the second wavelength may be increased. As such, the brightness and intensity of the finally obtained light having the second wavelength may be improved, and the high intensity of the emission light may contribute to the reduction of the power consumption of the light emitting device and the extension of the lifespan of the light emitting device.

As shown in FIG. 1A, the display panel 1 may include a plurality of light emitting devices 10 arranged in an array. Generally, the plurality of light emitting devices 10 are arranged at even intervals. For the sake of brevity and clarity, FIG. 1A shows several light emitting devices 10, and multiple light emitting devices 10 that are not shown are indicated by ellipsis “ . . . ”, but this does not mean that the display panel 1 merely includes the several light emitting devices 10 as shown in FIG. 1A. Those skilled in the art know that the display panel 1 can include a large number of light emitting devices 10.

According to the embodiments of the present disclosure, the display panel may be applicable to various appropriate fields, including but not limited to the display field, the automotive field, the medical field, and the like. For example, the display panel may be used for any suitable product or component such as a mobile phone, a tablet, a television, a monitor, a laptop, a digital photo frame, a navigator, an e-book, a car touch panel, a medical testing device, and the like.

According to the embodiments of the present disclosure, the first electrode 111 may be a reflective anode, and the second electrode 112 may be a reflective cathode which permits light to pass through. As such, the first electrode 111 and the second electrode 112 may form an optical resonator. The light emitting device 10 including the first electrode 111 and the second electrode 112 is a top-emitting type device, that is, the light emitting device 10 emits blue light and green light from a side of the second electrode 112 away from the first electrode 111. Electrode material(s) used for the first electrode 111 and the second electrode 112 may be adjusted appropriately according to actual needs. The first electrode 111 and the second electrode 112 may be disposed to face each other.

According to the embodiments of the present disclosure, the first electrode 111 may include a first ITO (Indium Tin Oxide) layer 1111, an Ag layer 1112, and a second ITO layer 1113. A thickness of the first electrode 111 may be in a range of 1160 Å to 1300 Å. For example, a thickness of the Ag layer may be 1000 Å, and a thickness of each ITO layer may be in a range of 80 Å to 150 Å. A process for preparing the first electrode 111 may be adjusted appropriately according to actual needs, for example, the ITO/Ag/ITO film layers may be formed by using a sputtering process.

According to embodiments of the present disclosure, a material of the second electrode 112 may be a semi-transparent and semi-reflective metal, such as one or more of Ag, Mg, Cu, Al, Pt, Pd, Au, Ni, Nd, Ir, Cr, Li, Ca, LiF/Ca, LiF/Al, Mo, and Ti. In some embodiments, a thickness of the second electrode 112 may be about in a range of 100 Å to 150 Å.

According to the embodiments of the present disclosure, the light having the first wavelength may be blue light, and the light having the second wavelength may be green light. In alternative embodiments, the light having the first wavelength and the light having the second wavelength may also be light of other appropriate colors, as long as they meet the condition that the first wavelength is smaller than the second wavelength.

With continuous reference to FIG. 1B, the light emitting device 10 may further include a first charge generating layer 131 between the first light emitting layer 121 and the second light emitting layer 122, a second charge generating layer 132 between the second light emitting layer 122 and the third light emitting layer 123, a third charge generating layer 133 between the third light emitting layer 123 and the fourth light emitting layer 124, and a fourth charge generating layer 134 between the fourth light emitting layer 124 and the fifth light emitting layer 125. In some embodiments, each of the first charge generating layer 131, second charge generating layer 132, third charge generating layer 133 and fourth charge generating layer 134 may include one of an n-type charge generating layer and a p-type charge generating layer. The first charge generating layer 131 may provide charges to the first light emitting layer 121 and the second light emitting layer 122, so as to control charges between the first light emitting layer 121 and the second light emitting layer 122 to be balanced. The second charge generating layer 132 may provide charges to the second light emitting layer 122 and the third light emitting layer 123, so as to control charges between the second light emitting layer 122 and the third light emitting layer 123. The third charge generating layer 133 may provide charges to the third light emitting layer 123 and the fourth light emitting layer 124, so as to control charges between the third light emitting layer 123 and the fourth light emitting layer 124 to be balanced. The fourth charge generating layer 134 may provide charges to the fourth light emitting layer 124 and the fifth light emitting layer 125, so as to control charges between the fourth light emitting layer 124 and the fifth light emitting layer 125 to be balanced. The provision of these charge generating layers may be conductive to the improvement of the light emitting efficiency of the light emitting device 10 and the reduction of a driving voltage for the light emitting device 10.

Referring to FIG. 1B, the light emitting device 10 may further include a charge injection layer 141 between the fifth light emitting layer 125 and the second electrode 112, and a CPL layer (capping layer) 142 on a side of the second electrode 112 away from the first electrode 111. Generally, when the light emitted by the light emitting layer of the light emitting device 10 is emitted outward passing through the second electrode 112, there will be a surface plasmon effect near an interface between the metal second electrode 112 and a medium, and the surface plasmon effect may cause a decrease in the light emitting efficiency. The existence of the CPL layer 142 may suppress this negative effect, so as to contribute to the improvement of the light emitting efficiency of the light emitting device 10.

Referring to FIG. 1B, at least one light emitting layer in the plurality of light emitting devices 10 includes one or two layers of a hole injection layer and a hole transport layer on a side close to the first electrode 111, and one or two layers of an electron transport layer and an electron injection layers away from the first electrode 111. For example, hole injection layers 1511, 1515, 1519, 1523 and 1527, hole transport layers 1512, 1516, 1520, 1524 and 1528, electron transport layers 1513, 1517, 1521, 1525 and 1529, and electron injection layers 1514, 1518, 1522, 1526 and 1530 may be provided between the first light emitting layer 121, the second light emitting layer 122, the third light emitting layer 123, the fourth light emitting layer 124 and the fifth light emitting layer 125 as desired.

It will be noted that a hole injection layer and a hole transport layer, though not shown in FIG. 1B, may be further provided between the first electrode 111 and the first light emitting layer 121, and an electron transport layer and an electron injection layer, though not shown in FIG. 1B, may be further provided between the fifth light emitting layer 125 and the second electrode layer 112.

According to the embodiments of the present disclosure, the light emitting device 10 may be an organic light emitting diode, and accordingly, the first light emitting layer 121, the second light emitting layer 122, the third light emitting layer 123, the fourth light emitting layer 124, and the fifth light emitting layer 125 are all organic light emitting layers.

According to the embodiments of the present disclosure, the light having the first wavelength emitted by the four light emitting layers forms a first standing wave in the light emitting device, and the light having the second wavelength emitted by the remaining light emitting layer forms a second standing wave in the light emitting device. For example, when the light having the first wavelength is blue light, the first standing wave may be a standing wave generated by blue light, and when the light having the second wavelength is green light, the second standing wave may be a standing wave generated by green light. In multiple embodiments of the present disclosure, various possible arrangements of the light emitting device are introduced by taking that the light having the first wavelength emitted by the light emitting device is blue light and the light having the second wavelength emitted by the light emitting device is green light as an example.

FIG. 1D schematically shows a schematic diagram of a standing wave and an antinode according to an embodiment of the present disclosure.

According to the embodiments of the present disclosure, in a case that the second light emitting layer 122, the third light emitting layer 123, the fourth light emitting layer 124 and the fifth light emitting layer 125 emit blue light and the first light emitting layer 121 emits green light, the blue light emitted by the second light emitting layer 122, the third light emitting layer 123, the fourth light emitting layer 124 and the fifth light emitting layer 125 forms a first standing wave W1 in the resonant cavity of the light emitting device 10, and the green light emitted by the first light emitting layer 121 forms a second standing wave W2 in the resonant cavity of the light emitting device 10. As known by those skilled in the art, a standing wave includes a node and an antinode, where the node refers to a point with the minimum amplitude on the standing wave and the antinode refers to a point with the maximum amplitude on the standing wave. The node is also known as node, and the antinode is also known as antinode.

According to the embodiments of the present disclosure, in the case that the second light emitting layer 122, the third light emitting layer 123, the fourth light emitting layer 124 and the fifth light emitting layer 125 emit blue light and the first light emitting layer 121 emits green light, a surface of the first electrode 111 facing the first light emitting layer 121 serves as a reference surface, the second light emitting layer 122 is located at a second antinode W12 of the first standing wave W1, the third light emitting layer 123 is located at a third antinode W13 of the first standing wave W1, the fourth light emitting layer 124 is located at a fourth antinode W14 of the first standing wave W1, the fifth light emitting layer 125 is located at a fifth antinode W15 of the first standing wave W1, and the first light emitting layer 121 is located at a first antinode W21 of the second standing wave W2.

According to the embodiments of the present disclosure, in the microcavity OLED, the position where the light emitting layer is disposed in the microcavity affects the luminance of the light emitting layer. The light emitted from the light emitting layer can form a standing wave in the microcavity. When the light emitting position of the light emitting layer is disposed at a position where an antinode of the standing wave is located, the microcavity effect may be strengthened, so as to enhance the luminous intensity, so that the light emitting efficiency of the light emitting device may be improved and the intensity of the emission light may be enhanced. The number of antinode positions varies as the length of the microcavity varies.

The second light emitting layer 122, the third light emitting layer 123, the fourth light emitting layer 124 and the fifth light emitting layer 125 are all located at the antinode positions of the first standing wave, thus the blue light emitted by the second light emitting layer 122, the third light emitting layer 123, the fourth light emitting layer 124 and the fifth light emitting layer 125 may generate constructive interference to enhance the output intensity of the blue light. The first light emitting layer 121 is located at the antinode position of the second standing wave, and the green light emitted by the first light emitting layer 121 may generate constructive interference to enhance the output intensity of the green light.

According to the embodiments of the present disclosure, a first distance X1 from a first surface of the first electrode 111 close to the first light emitting layer 121 to a surface of the first light emitting layer 121 on a side away from the first electrode 111 may be less than 500 Å, such as 150 Å, 200 Å, 250 Å, 300 Å, 350 Å, 400 Å, and 450 Å. Specifically, in the case that the first electrode 111 is ITO/Ag/ITO, the first surface may be a surface of the first ITO layer 1111 on a side away from the first light emitting layer 121, and correspondingly, the first distance X1 may be a distance from the surface of the first ITO layer 1111 on the side away from the first light emitting layer 121 to the surface of the first light emitting layer 121 on the side away from the first electrode 111. An appropriate first distance X1 may reduce the problem of the reduction of the light emitting efficiency caused by the surface plasmon effect generated near the interface between the first electrode 111 and the first light emitting layer 121, and further, an appropriate first distance X1 may improve the light emitting efficiency of the light emitting device. Within a region of X1, the light emitted here may be the strongest.

FIG. 1C schematically shows a relationship between a cavity length thickness and an emission spectrum of a light emitting device according to an embodiment of the present disclosure.

As shown in FIG. 1C, the horizontal axis represents a thickness of the electron transport layer, and the vertical axis represents a thickness of the hole transport layer. In a case that the horizontal and vertical coordinates take a same thickness value, a diagonal of a quadrilateral formed according to the horizontal and vertical coordinates may be considered as a cavity length thickness of the overall resonant cavity of the light emitting device. The spectrum under this cavity length thickness or appearing on this diagonal is the light that can be emitted by the light emitting device under this cavity length thickness. Red represents light in a red wave band, green represents light in a green wave band, and blue represents light in a blue wave band. According to FIG. 1C, a cavity length thickness corresponding to the condition that one or more of the blue light, green light, or red light reach their respective strongest luminous intensities simultaneously may be obtained. For example, in a case that the thickness of each of the electron transport layer and the hole transport layer is 400 nm, the light in the red wave band and the light in the blue wave band have large proportions on the diagonal of the quadrilateral formed according to the horizontal and vertical coordinates. In a case that the thickness of each of the electron transport layer and the hole transport layer is 500 nm, the light in the green wave band and the light in the blue wave band have large proportions on the diagonal of the quadrilateral formed according to the horizontal and vertical coordinates. If it is required to obtain light in different wave bands, or light in a certain wave band is required to be emitted with the strongest luminous intensity, a corresponding cavity length thickness may be found visually according to FIG. 1C.

According to the embodiments of the present disclosure, in the case that the second light emitting layer 122, the third light emitting layer 123, the fourth light emitting layer 124 and the fifth light emitting layer 125 emit blue light, and the first light emitting layer 121 emits green light, a second distance X2 between the first electrode 111 and the second electrode 112 may be equal to 5 times a distance between two adjacent antinodes of the first standing wave or 4 times a distance between two adjacent antinodes of the second standing wave. This distance may also be understood as that, in the light emitting device, the blue light may have the strongest luminous intensity at five positions, and correspondingly, the green light may have the strongest luminous intensity at four positions. The second distance X2 is the cavity length of the resonant cavity of the light emitting device 10. There is no positive correlation between the thickness of the cavity length and the light emitting efficiency of the light emitting device, since the larger the cavity length of the resonant cavity is, the more light emitting layers are required in the light emitting device, which may cause an increased driving voltage and increase the power consumption of the light emitting device. In addition, as the cavity length is large, multiple reflections may occur in the resonant cavity, so that more light may be absorbed and the light output efficiency of the light emitting device may be reduced. Moreover, considering the uniformity in an evaporation plating process during the preparation process, the first distance X2 should not be set too large.

According to the embodiments of the present disclosure, the light emission peaks of the second light emitting layer 122, the third light emitting layer 123, the fourth light emitting layer 124, and the fifth light emitting layer 125 are at a same position, and the thickness of each light emitting layer may be in a range of 200 Å to 250 Å. The thickness of the first light emitting layer 121 may be in a range of 300 Å to 350 Å.

According to the embodiments of the present disclosure, in a case that the cavity length of the light emitting device, the first distance X1, the thickness of the first electrode 111, the thickness of the second electrode 112, and the thickness of each light emitting layer is determined, the thicknesses of the hole injection layer, the hole transport layer, the electron transport layer, the electron injection layer and other layers which are provided as desired in the light emitting device may be obtained by calculation, and the thicknesses of these layers may also be adjusted adaptively according to actual needs.

FIG. 1E schematically shows a spectrogram of light emitted by a light emitting device according to an embodiment of the present disclosure, where a first light emitting layer of the light emitting device emits green light.

The spectrum of the emission light is shown in FIG. 1E, where the light is emitted by the light emitting device 10 after passing through the QD. In FIG. 1E, the horizontal axis represents the wavelength, and the vertical axis represents the luminous intensity. The curves of the three lights in FIG. 1E respectively represent blue light, green light, and red light. It can be seen from FIG. 1E that when the first light emitting layer 121 emits green light, the light emitted by the light emitting device 10 has a narrow full width at half maxima.

According to the embodiments of the present disclosure, by disposing the second light emitting layer 122, the third light emitting layer 123, the fourth light emitting layer 124 and the fifth light emitting layer 125 of the light emitting device 10 at the second, third, fourth and fifth antinodes of the first standing wave, respectively, the blue light emitted by them may generate constructive interference, so as to enhance the output intensity of the blue light. By disposing the first light emitting layer 121 of the light emitting device 10 at the first antinode of the second standing wave, the green light emitted by the first light emitting layer 121 may be brought to the best resonance position, so that the luminance of the green light may be maximized. After the light of the OLED passes through the QD conversion layer, when green light is expected to be obtained through the light emitting device 10, the blue light emitted by the light emitting device 10 may be converted into green light, and the converted green light and the green light emitted by the light emitting device 10 may be superposed to serve as the finally obtained green light. When red light is expected to be obtained through the light emitting device 10, blue light and green light emitted by the light emitting device 10 may also be converted into red light. In this way, not only the requirements for high luminance and high intensity of the emission light by the light emitting device 10 may be realized by using the characteristics of the spectrum of the blue light with the narrow half-wave width, but also the green light emitted by the light emitting device 10 itself may be used as a supplementary light source, so that a total amount of the obtained green or red light may be increased. As such, the luminance and intensity of the finally obtained green or red light may be improved, which may contribute to the reduction of the power consumption of the light emitting device and the extension of the lifespan of the light emitting device.

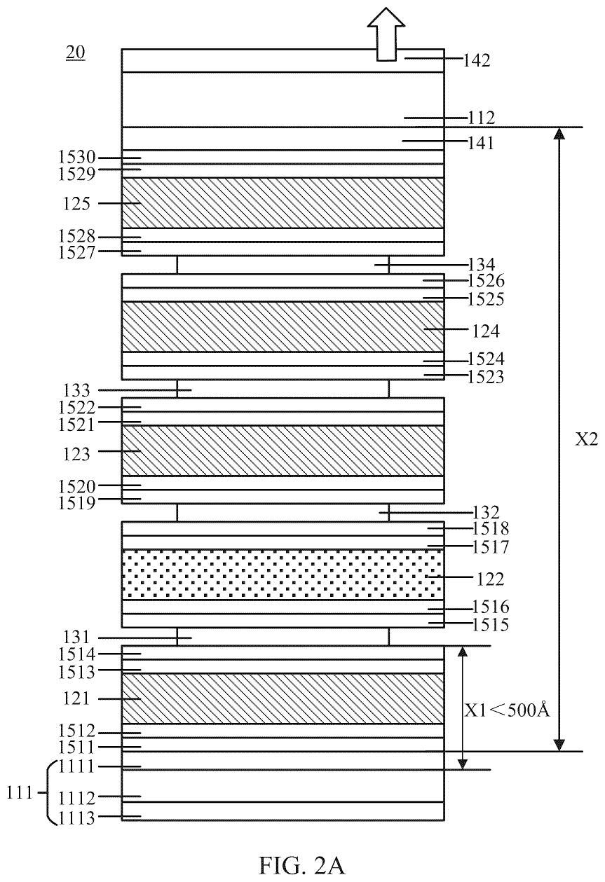

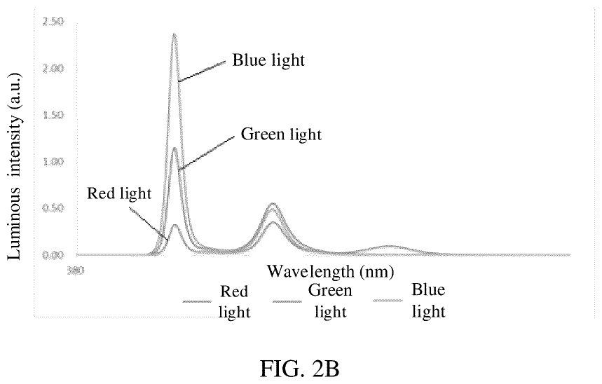

FIG. 2A schematically shows a sectional view of a light emitting device according to another embodiment of the present disclosure.

As shown in FIG. 2A, the light emitting device 20 is a variant of the light emitting device 10. The light emitting device 20 shown in FIG. 2A has substantially the same construction as the light emitting device 10 shown in FIG. 1B, and the same reference signs are used to indicate the same components. Accordingly, the specific structures and functions of the components in FIG. 2A, which have the same reference signs as those in FIG. 1B, may be referred to the description for FIG. 1B, and details will not be repeated here. For the sake of brevity, only the differences between the light emitting device 20 and the light emitting device 10 are described below.

According to the embodiments of the present disclosure, the light emitting device 20 differs from the light emitting device 10 in that the first light emitting layer 121, the third light emitting layer 123, the fourth light emitting layer 124 and the fifth light emitting layer 125 emit blue light, and the second light emitting layer 122 emits green light.

According to the embodiments of the present disclosure, in the light emitting device 20, the blue light emitted by the first light emitting layer 121, the third light emitting layer 123, the fourth light emitting layer 124, and the fifth light emitting layer 125 forms the first standing wave in the resonant cavity of the light emitting device 20, and the green light emitted by the second light emitting layer 122 forms the second standing wave in the resonant cavity of the light emitting device 20.

According to the embodiments of the present disclosure, in the case that the first light emitting layer 121, the third light emitting layer 123, the fourth light emitting layer 124 and the fifth light emitting layer 125 emit blue light and the second light emitting layer 122 emits green light, the surface of the first electrode 111 facing the first light emitting layer 121 serves as a reference surface, the first light emitting layer 121 is located at a first antinode of the first standing wave, the third light emitting layer 123 is located at a third antinode of the first standing wave, the fourth light emitting layer 124 is located at a fourth antinode of the first standing wave, the fifth light emitting layer 125 is located at a fifth antinode of the first standing wave, and the second light emitting layer 122 is located at a second antinode of the second standing wave.

The first light emitting layer 121, the third light emitting layer 123, the fourth light emitting layer 124, and the fifth light emitting layer 125 are all located at the antinode positions of the first standing wave, thus the blue light emitted by the first light emitting layer 121, the third light emitting layer 123, the fourth light emitting layer 124, and the fifth light emitting layer 125 may generate constructive interference to enhance the output intensity of the blue light. The second light emitting layer 122 is located at the antinode position of the second standing wave, and the green light emitted by the second light emitting layer 122 may generate constructive interference to enhance the output intensity of the green light.

According to the embodiments of the present disclosure, the first distance X1 in the light emitting device 20 may be less than 500 Å, such as 150 Å, 200 Å. 250 Å, 300 Å, 350 Å, 400 Å, and 450 Å. In the case that the first light emitting layer 121, the third light emitting layer 123, the fourth light emitting layer 124 and the fifth light emitting layer 125 emit blue light and the second light emitting layer 122 emits green light, the second distance X2 between the first electrode 111 and the second electrode 112 may be equal to 5 times a distance between two adjacent antinodes of the first standing wave or 4 times a distance between two adjacent antinodes of the second standing wave.

FIG. 2B schematically shows a spectrogram of light emitted by a light emitting device according to an embodiment of the present disclosure, where a second light emitting layer of the light emitting device emits green light.

The spectrum of the emission light is shown in FIG. 2B, where the light is emitted by the light emitting device 20 after passing through the QD. In FIG. 2B, the horizontal axis represents the wavelength, and the vertical axis represents the luminous intensity. The curves of the three lights in FIG. 2B respectively represent blue light, green light, and red light. It can be seen from FIG. 2B that, when the second light emitting layer 122 emits green light, all the light emitted by the light emitting device 20 has a narrow full width at half maxima.

According to the embodiments of the present disclosure, by disposing the first light emitting layer 121, the third light emitting layer 123, the fourth light emitting layer 124 and the fifth light emitting layer 125 of the light emitting device 20 at the first, third, fourth and fifth antinodes of the first standing wave, respectively, the blue light emitted by them may generate constructive interference, so as to enhance the output intensity of the blue light; and by disposing the second light emitting layer 122 of the light emitting device 20 at the second antinode of the second standing wave, the green light emitted by the second light emitting layer 122 may be brought to the best resonance position, so that the luminance of the green light may be maximized. After the light of the OLED passes through the QD conversion layer, when green light is expected to be obtained through the light emitting device 20, the blue light emitted by the light emitting device 20 may be converted into green light, and the converted green light and the green light emitted by the light emitting device 20 may be superposed to serve as the finally obtained green light. When red light is expected to be obtained through the light emitting device 20, blue light and green light emitted by the light emitting device 20 may also be converted into red light. In this way, not only the requirements for high luminance and high intensity of the emission light by the light emitting device 20 may be realized by using the characteristics of the spectrum of the blue light with the narrow half-wave width, but also the green light emitted by the light emitting device 20 itself may be used as a supplementary light source, so that a total amount of the obtained green or red light may be increased. As such, the luminance and intensity of the finally obtained green or red light may be improved, which may contribute to the reduction of the power consumption of the light emitting device and the extension of the lifespan of the light emitting device.

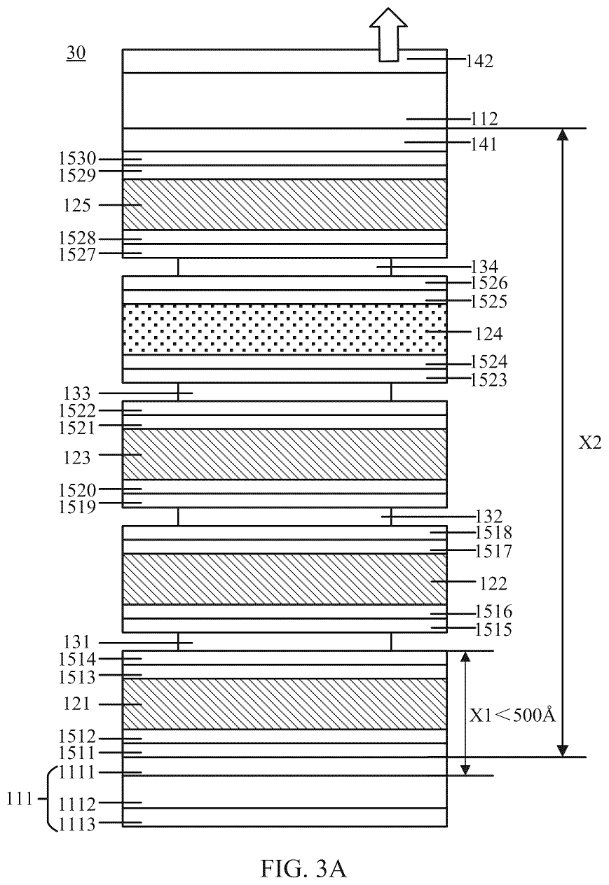

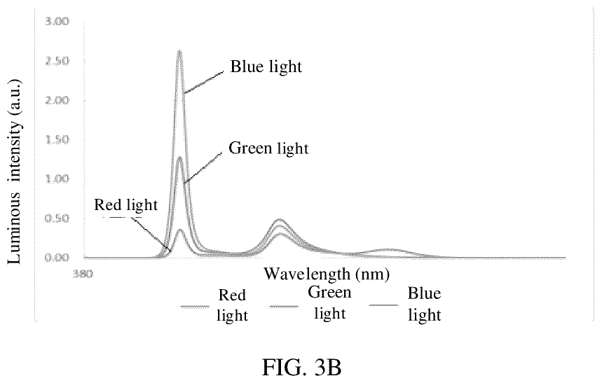

FIG. 3A schematically shows a sectional view of a light emitting device according to another embodiment of the present disclosure.

As shown in FIG. 3A, a light emitting device 30 is a variant of the light emitting device 10. The light emitting device 30 shown in FIG. 3A has a substantially same construction as the light emitting device 10 shown in FIG. 1B, and the same reference signs are used to indicate the same components. Accordingly, the specific structures and functions of the components in FIG. 3A, which have the same reference signs as those in FIG. 1B, may be referred to the description for FIG. 1B, and details will not be repeated here. For the sake of brevity, only the differences between the light emitting device 30 and the light emitting device 10 are described below.

According to the embodiments of the present disclosure, the light emitting device 30 differs from the light emitting device 10 in that the first light emitting layer 121, the second light emitting layer 122, the third light emitting layer 123 and the fifth light emitting layer 125 emit blue light, and the fourth light emitting layer 124 emits green light.

According to the embodiments of the present disclosure, in the light emitting device 30, the blue light emitted by the first light emitting layer 121, the second light emitting layer 122, the third light emitting layer 123 and the fifth light emitting layer 125 forms the first standing wave in the resonant cavity of the light emitting device 30, and the green light emitted by the fourth light emitting layer 124 forms the second standing wave in the resonant cavity of the light emitting device 30.

According to the embodiments of the present disclosure, in the case that the first light emitting layer 121, the second light emitting layer 122, the third light emitting layer 123 and the fifth light emitting layer 125 emit blue light and the fourth light emitting layer 124 emits green light, the surface of the first electrode 111 facing the first light emitting layer 121 serves as a reference surface, the first light emitting layer 121 is located at a first antinode of the first standing wave, the second light emitting layer 122 is located at a second antinode of the first standing wave, the third light emitting layer 123 is located at a third antinode of the first standing wave, the fifth light emitting layer 125 is located at a fifth antinode of the first standing wave, and the fourth light emitting layer 124 is located at a third antinode of the second standing wave.

The first light emitting layer 121, the second light emitting layer 122, the third light emitting layer 123, and the fifth light emitting layer 125 are all located at the antinode positions of the first standing wave, thus the blue light emitted by the first light emitting layer 121, the second light emitting layer 122, the third light emitting layer 123, and the fifth light emitting layer 125 may generate constructive interference to enhance the output intensity of the blue light. The fourth light emitting layer 124 is located at the antinode position of the second standing wave, and the green light emitted by the fourth light emitting layer 124 may generate constructive interference to enhance the output intensity of the green light.

According to the embodiments of the present disclosure, the first distance X1 in the light emitting device 30 may be less than 500 Å, such as 150 Å, 200 Å, 250 Å, 300 Å. 350 Å, 400 Å and 450 Å. In the case that the first light emitting layer 121, the second light emitting layer 122, the third light emitting layer 123, and the fifth light emitting layer 125 emit blue light and the fourth light emitting layer 124 emits green light, the second distance X2 between the first electrode 111 and the second electrode 112 may be equal to 5 times a distance between two adjacent antinodes of the first standing wave or 4 times a distance between two adjacent antinodes of the second standing wave.

FIG. 3B schematically shows a spectrogram of light emitted by a light emitting device according to an embodiment of the present disclosure, where a fourth light emitting layer of the light emitting device emits green light.

The spectrum of the emission light is shown in FIG. 3B, where the light is emitted by the light emitting device 30 after passing through the QD. In FIG. 3B, the horizontal axis in FIG. 3B represents the wavelength, and the vertical axis represents the luminous intensity. The curves of the three lights in FIG. 3B respectively represent blue light, green light, and red light. It can be seen from FIG. 3B that, when the fourth light emitting layer 124 emits green light, all the light emitted by the light emitting device 30 has a narrow full width at half maxima.

According to the embodiments of the present disclosure, by disposing the first light emitting layer 121, the second light emitting layer 122, the third light emitting layer 123 and the fifth light emitting layer 125 of the light emitting device 30 at the first, second, third and fifth antinodes of the first standing wave, respectively, the blue light emitted by them may generate constructive interference, so as to enhance the output intensity of the blue light; and by disposing the fourth light emitting layer 124 of the light emitting device 30 at the third antinode of the second standing wave, the green light emitted by the fourth light emitting layer 124 may be brought to the best resonance position, so that the luminance of the green light may be maximized. After the light of the OLED passes through the QD conversion layer, when green light is expected to be obtained through the light emitting device 30, the blue light emitted by the light emitting device 30 may be converted into green light, and the converted green light and the green light emitted by the light emitting device 30 may be superposed to serve as the finally obtained green light. When red light is expected to be obtained through the light emitting device 30, blue light and green light emitted by the light emitting device 30 may also be converted into red light. In this way, not only the requirements for high luminance and high intensity of the emission light by the light emitting device 30 may be realized by using the characteristics of the spectrum of the blue light with the narrow half-wave width, but also the green light emitted by the light emitting device 30 itself may be used as a supplementary light source, so that a total amount of the obtained green or red light may be increased. As such, the luminance and intensity of the finally obtained green or red light may be improved, which may contribute to the reduction of the power consumption of the light emitting device and the extension of the lifespan of the light emitting device.

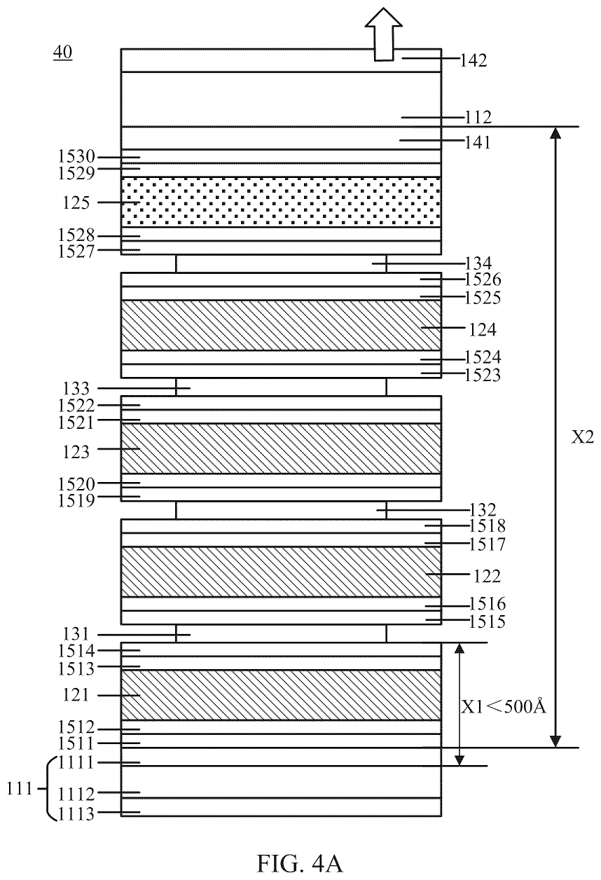

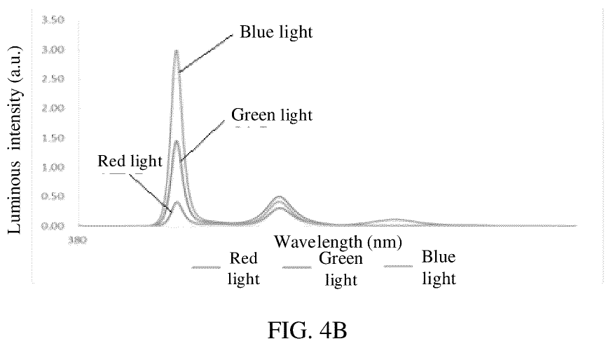

FIG. 4A schematically shows a sectional view of a light emitting device according to another embodiment of the present disclosure.

As shown in FIG. 4A, the light emitting device 40 is a variant of the light emitting device 10. The light emitting device 40 shown in FIG. 4A has substantially the same construction as the light emitting device 10 shown in FIG. 1B, and therefore the same reference signs are used to indicate the same components. Accordingly, the specific structures and functions of the components in FIG. 4A, which have the same reference signs as those in FIG. 1B, may be referred to the description for FIG. 1B, and details will not be repeated here. For the sake of brevity, only the differences between the light emitting device 40 and the light emitting device 10 are described below.

According to the embodiments of the present disclosure, the light emitting device 40 differs from the light emitting device 10 in that the first light emitting layer 121, the second light emitting layer 122, the third light emitting layer 123 and the fourth light emitting layer 124 emit blue light, and the fifth light emitting layer 125 emits green light.

According to the embodiments of the present disclosure, in the light emitting device 40, the blue light emitted by the first light emitting layer 121, the second light emitting layer 122, the third light emitting layer 123 and the fourth light emitting layer 124 forms the first standing wave in the resonant cavity of the light emitting device 40, and the green light emitted by the fifth light emitting layer 125 forms the second standing wave in the resonant cavity of the light emitting device 40.

According to the embodiments of the present disclosure, in the case that the first light emitting layer 121, the second light emitting layer 122, the third light emitting layer 123 and the fourth light emitting layer 124 emit blue light and the fifth light emitting layer 125 emit green light, the surface of the first electrode 111 facing the first light emitting layer 121 serves as a reference surface, the first light emitting layer 121 is located at a first antinode of the first standing wave, the second light emitting layer 122 is located at a second antinode of the first standing wave, the third light emitting layer 123 is located at a third antinode of the first standing wave, the fourth light emitting layer 124 is located at a fourth antinode of the first standing wave, and the fifth light emitting layer 125 is located at a fourth antinode of the second standing wave.

The first light emitting layer 121, the second light emitting layer 122, the third light emitting layer 123, and the fourth light emitting layer 124 are all located at the antinode positions of the first standing wave, thus the blue light emitted by the first light emitting layer 121, the second light emitting layer 122, the third light emitting layer 123, and the fourth light emitting layer 124 may generate constructive interference to enhance the output intensity of the blue light. The fifth light emitting layer 125 is located at the antinode position of the second standing wave, and the green light emitted by the fifth light emitting layer 125 may generate constructive interference to enhance the output intensity of the green light.

According to the embodiments of the present disclosure, the first distance X1 in the light emitting device 40 may be less than 500 Å, such as 150 Å, 200 Å, 250 Å, 300 Å, 350 Å, 400 Å, and 450 Å. In the case that the first light emitting layer 121, the second light emitting layer 122, the third light emitting layer 123, and the fourth light emitting layer 124 emit blue light and the fifth light emitting layer 125 emits green light, the second distance X2 between the first electrode 111 and the second electrode 112 may be equal to 5 times a distance between two adjacent antinodes of the first standing wave or 4 times a distance between two adjacent antinodes of the second standing wave.

FIG. 4B schematically shows a spectrogram of light emitted by a light emitting device according to an embodiment of the present disclosure, where a fifth light emitting layer of the light emitting device emits green light.

The spectrum of the emission light is shown in FIG. 4B, where the light is emitted by the light emitting device 40 after passing through the QD. In FIG. 4B, the horizontal axis represents the wavelength, and the vertical axis represents the luminous intensity. The curves of the three lights in FIG. 4B respectively represent blue light, green light, and red light. It can be seen from FIG. 4B that, when the fifth light emitting layer 125 emits green light, all the light emitted by the light emitting device 40 has a narrow full width at half maxima.

According to embodiments of the present disclosure, by disposing the first light emitting layer 121, the second light emitting layer 122, the third light emitting layer 123 and the fourth light emitting layer 124 of the light emitting device 40 at the first, second, third and fourth antinodes of the first standing wave, respectively, the blue light emitted by them generate constructive interference, so as to enhance the output intensity of the blue light; and by disposing the fifth light emitting layer 125 of the light emitting device 40 at the fourth antinode of the second standing wave, the green light emitted by the fifth light emitting layer 125 may be brought to the best resonance position, so that the luminance of the green light may be maximized. After the light of the OLED passes through the QD conversion layer, when green light is expected to be obtained through the light emitting device 40, the blue light emitted by the light emitting device 40 may be converted into green light, and the converted green light and the green light emitted by the light emitting device 40 may be superposed to serve as the finally obtained green light. When red light is expected to be obtained through the light emitting device 40, blue light and green light emitted by the light emitting device 40 may also be converted into red light. In this way, not only the requirements for high luminance and high intensity of the emission light by the light emitting device 40 may be realized by using the characteristics of the spectrum of the blue light with the narrow half-wave width, but also the green light emitted by the light emitting device 40 itself may be used as a supplementary light source, so that a total amount of the obtained green or red light may be increased. As such, the luminance and intensity of the finally obtained green or red light may be improved, which may contribute to the reduction of the power consumption of the light emitting device and the extension of the lifespan of the light emitting device.

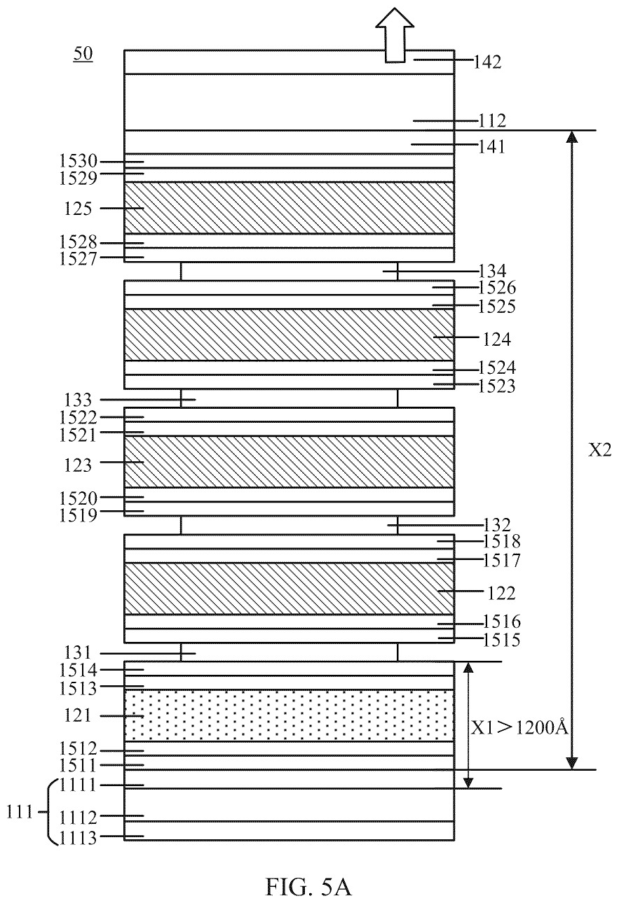

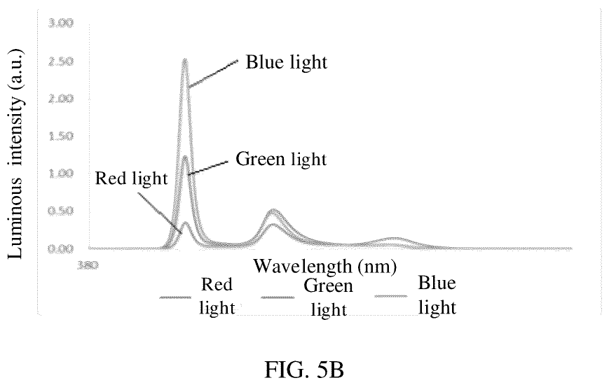

FIG. 5A schematically shows a sectional view of a light emitting device according to another embodiment of the present disclosure.

As shown in FIG. 5A, a light emitting device 50 is a variant of the light emitting device 10. The light emitting device 50 shown in FIG. 5A has substantially the same construction as the light emitting device 10 shown in FIG. 1B, and therefore the same reference signs are used to refer to the same components. Accordingly, the specific structures and functions of the components in FIG. 5A, which have the same reference signs as those in FIG. 1B, may be referred to the description for FIG. 1B, and details will not be repeated here. For the sake of brevity, only the differences between the light emitting device 50 and the light emitting device 10 are described below.

According to the embodiments of the present disclosure, the second light emitting layer 122, the third light emitting layer 123, the fourth light emitting layer 124 and the fifth light emitting layer 125 of the light emitting device 50 emit blue light, and the first light emitting layer 121 emits green light. The difference between the light emitting device 50 and the light emitting device 10 is that the first distance from the first surface of the first electrode 111 close to the first light emitting layer 121 to the surface of the first light emitting layer 121 on a side away from the first electrode 111 is greater than 1200 Å, such as 1250 Å, 1300 Å, and 1500 Å. Specifically, in the case that the first electrode 111 is ITO/Ag/ITO, the first surface may be a surface of the first ITO layer 1111 on a side away from the first light emitting layer 121, and correspondingly, the first distance X1 may be a distance from a surface of the first ITO layer 1111 on a side away from the first light emitting layer 121 to a surface of the first light emitting layer 121 on a side away from the first electrode 111. The first distance X1 may be not only less than 500 Å, but also greater than 1200 Å. An appropriate first distance X1 may reduce the surface plasmon polariton effect near the interface between the first electrode 111 and the first light emitting layer 121, and may improve the light emitting efficiency of the light emitting device.

According to the embodiments of the present disclosure, in the light emitting device 50, the blue light emitted by the second light emitting layer 122, the third light emitting layer 123, the fourth light emitting layer 124 and the fifth light emitting layer 125 forms a first standing wave in the resonant cavity of the light emitting device 50, and the green light emitted by the first light emitting layer 121 forms a second standing wave in the resonant cavity of the light emitting device 50.

According to the embodiments of the present disclosure, in the case that the second light emitting layer 122, the third light emitting layer 123, the fourth light emitting layer 124 and the fifth light emitting layer 125 emit blue light, the first light emitting layer 121 emits green light, and X1 is greater than 1200 Å, the surface of the first electrode 111 facing the first light emitting layer 121 serves as a reference surface, the second light emitting layer 122 is located at a third antinode of the first standing wave, the third light emitting layer 123 is located at a fourth antinode of the first standing wave, the fourth light emitting layer 124 is located at a fifth antinode of the first standing wave, the fifth light emitting layer 125 is located at a sixth antinode of the first standing wave, and the first light emitting layer 121 is located at a second antinode of the second standing wave.

The second light emitting layer 122, third light emitting layer 123, fourth light emitting layer 124, and fifth light emitting layer 125 are all disposed at the antinode positions of the first standing wave, thus the blue light emitted by the second light emitting layer 122, the third light emitting layer 123, the fourth light emitting layer 124, and the fifth light emitting layer 125 may generate constructive interference to enhance the output intensity of the blue light. The first light emitting layer 121 is disposed at the antinode position of the second standing wave, and the green light emitted by the first light emitting layer 121 may generate constructive interference to enhance the output intensity of the green light.

According to the embodiments of the present disclosure, in the light emitting device 50, in the case that the second light emitting layer 122, the third light emitting layer 123, the fourth light emitting layer 124, and the fifth light emitting layer 125 emit blue light, and the first light emitting layer 121 emits green light, and X1 is greater than 1200 Å, the second distance X2 between the first electrode 111 and the second electrode 112 may be equal to 6 times a distance between two adjacent antinodes of the first standing wave or 5 times a distance between two adjacent antinodes of the second standing wave. Therefore, in the embodiment, if X1 is greater than 1200 Å, the cavity length will be lengthened. Setting the second distance X2 as 6 times the distance between two adjacent antinodes of the first standing wave or 5 times the distance between two adjacent antinodes of the second standing wave may improve the light output efficiency of the light emitting device and reduce the power consumption at the same time.

According to embodiments of the present disclosure, in the case that X1 is greater than 1200 Å, the thickness of the first electrode 111 and the thickness of the first light emitting layer 121 are the same as the thicknesses of the corresponding layers in the light emitting device 10, and the increase is achieved mainly by increasing the thickness of the hole transport layer.

FIG. 5B schematically shows a spectrogram of light emitted by a light emitting device according to an embodiment of the present disclosure, where a second distance is greater than 1200 Å.

The spectrum of the emission light is shown in FIG. 5B, where the light is emitted by the light emitting device 50 after passing through the QD. In FIG. 5B, the horizontal axis represents the wavelength, and the vertical axis represents the luminous intensity. The curves of the three lights in FIG. 5B respectively represent blue light, green light, and red light. It can be seen from FIG. 5B that, when the second distance is greater than 1200 Å, the emission light emitted by the light emitting device 50 has a narrow full width at half maxima.

According to the embodiments of the present disclosure, by disposing the second light emitting layer 122, the third light emitting layer 123, the fourth light emitting layer 124, and the fifth light emitting layer 125 of the light emitting device 50 at the third, fourth, fifth, and sixth antinodes of the first standing wave, respectively, the blue light emitted by them may generate constructive interference to enhance the output intensity of the blue light; and by disposing the first light emitting layer 121 of the light emitting device 50 at the second antinode of the second standing wave, the green light emitted by the first light emitting layer 121 may be brought to the best resonance position, so that the luminance of the green light may be maximized. After the light of the OLED passes through the QD conversion layer, when green light is expected to be obtained through the light emitting device 50, the blue light emitted by the light emitting device 50 may be converted into green light, and the converted green light and the green light emitted by the light emitting device 50 may be superposed to serve as the finally obtained green light. When red light is expected to be obtained through the light emitting device 50, blue light and green light emitted by the light emitting device 50 may also be converted into red light. In this way, not only the requirements for high luminance and high intensity of the emission light by the light emitting device 50 may be realized by using the characteristics of the spectrum of the blue light with the narrow half-wave width, but also the green light emitted by the light emitting device 50 itself may be used as a supplementary light source, so that a total amount of the obtained green or red light may be increased. As such, the luminance and intensity of the finally obtained green or red light may be improved, which may contribute to the reduction of the power consumption of the light emitting device and the extension of the lifespan of the light emitting device.

According to the embodiments of the present disclosure, in the above-mentioned light emitting device, a material of the light emitting layer for emitting blue light may be a fluorescent light emitting material, and a material of the light emitting layer for emitting green light may be a phosphorescent light emitting material.

According to the embodiments of the present disclosure, in the structure of the display panel, a wavelength conversion layer may be further provided on a side of the second electrode away from the first electrode. A material of the wavelength conversion layer may be a quantum dot material, which is used to absorb light and then emit light having an inherent wavelength.

According to the embodiments of the present disclosure, there is further provided a display apparatus, and the display apparatus includes the display panel described in any of the above-mentioned embodiments. The display apparatus may be any product or component with a display function, such as a mobile phone, a tablet computer, a television, a monitor, a laptop, a digital photo frame, a navigator, and the like.

The display apparatus provided in the embodiments of the present disclosure includes the above-mentioned display panel, and the beneficial effects of the display apparatus are the same as those of the above-mentioned display panel, and details will not be repeated here.

Although some embodiments of the general concept of the present disclosure have been illustrated and described, those skilled in the art will understand that changes may be made to these embodiments without departing from the principles and spirit of the general inventive concept of the present disclosure. The scope of the present disclosure is defined by the claims and their equivalents.

1. A display panel, comprising a plurality of light emitting devices arranged in an array, wherein each of the plurality of light emitting devices comprises:
a first electrode;
a first light emitting layer on the first electrode;
a second light emitting layer on a side of the first light emitting layer away from the first electrode;
a third light emitting layer on a side of the second light emitting layer away from the first electrode;
a fourth light emitting layer on a side of the third light emitting layer away from the first electrode;
a fifth light emitting layer on a side of the fourth light emitting layer away from the first electrode; and
a second electrode on a side of the fifth light emitting layer away from the first electrode,
wherein:
a microcavity is formed between the first electrode and the second electrode;
four light emitting layers among the first light emitting layer, the second light emitting layer, the third light emitting layer, the fourth light emitting layer and the fifth light emitting layer emit light having a first wavelength; and
a remaining light emitting layer, other than the four light emitting layers emitting the light having the first wavelength, among the first light emitting layer, the second light emitting layer, the third light emitting layer, the fourth light emitting layer and the fifth light emitting layer emits light having a second wavelength, wherein the first wavelength is smaller than the second wavelength.

2. The display panel according to claim 1, wherein the light having the first wavelength emitted by the four light emitting layers forms a first standing wave in the light emitting device, and the light having the second wavelength emitted by the remaining light emitting layer forms a second standing wave in the light emitting device.

3. The display panel according to claim 2, wherein a first distance from a first surface of the first electrode close to the first light emitting layer to a surface of the first light emitting layer on a side away from the first electrode is less than 500 Å.

4. The display panel according to claim 2, wherein the second light emitting layer, the third light emitting layer, the fourth light emitting layer and the fifth light emitting layer emit blue light, and the first light emitting layer emits green light.

5. The display panel according to claim 4, wherein a surface of the first electrode facing the first light emitting layer serves as a reference surface, the second light emitting layer is located at a second antinode of the first standing wave, the third light emitting layer is located at a third antinode of the first standing wave, the fourth light emitting layer is located at a fourth antinode of the first standing wave, the fifth light emitting layer is located at a fifth antinode of the first standing wave, and the first light emitting layer is located at a first antinode of the second standing wave.

6. The display panel according to claim 2, wherein the first light emitting layer, the third light emitting layer, the fourth light emitting layer and the fifth light emitting layer emit blue light, and the second light emitting layer emits green light.

7. The display panel according to claim 6, wherein a surface of the first electrode facing the first light emitting layer serves as a reference surface, the first light emitting layer is located at a first antinode of the first standing wave, the third light emitting layer is located at a third antinode of the first standing wave, the fourth light emitting layer is located at a fourth antinode of the first standing wave, the fifth light emitting layer is located at a fifth antinode of the first standing wave, and the second light emitting layer is located at a second antinode of the second standing wave.

8. The display panel according to claim 2, wherein the first light emitting layer, the second light emitting layer, the third light emitting layer and the fifth light emitting layer emit blue light, and the fourth light emitting layer emits green light.

9. The display panel according to claim 8, wherein a surface of the first electrode facing the first light emitting layer serves as a reference surface, the first light emitting layer is located at a first antinode of the first standing wave, the second light emitting layer is located at a second antinode of the first standing wave, and the third light emitting layer is located at a third antinode of the first standing wave, the fifth light emitting layer is located at a fifth antinode of the first standing wave, and the fourth light emitting layer is located at a third antinode of the second standing wave.

10. The display panel according to claim 2, wherein the first light emitting layer, the second light emitting layer, the third light emitting layer, and the fourth light emitting layer emit blue light, and the fifth light emitting layer emits green light.

11. The display panel according to claim 10, wherein a surface of the first electrode facing the first light emitting layer serves as a reference surface, the first light emitting layer is located at a first antinode of the first standing wave, the second light emitting layer is located at a second antinode of the first standing wave, and the third light emitting layer is located at a third antinode of the first standing wave, the fourth light emitting layer is located at a fourth antinode of the first standing wave, and the fifth light emitting layer is located at a fourth antinode of the second standing wave.

12. The display panel according to claim 2, wherein a second distance between the first electrode and the second electrode is equal to 5 times a distance between two adjacent antinodes of the first standing wave or 4 times a distance between two adjacent antinodes of the second standing wave; or
wherein a second distance between the first electrode and the second electrode is equal to 6 times a distance between two adjacent antinodes of the first standing wave or 5 times a distance between two adjacent antinodes of the second standing wave.

13. The display panel according to claim 2, wherein a first distance from a first surface of the first electrode close to the first light emitting layer to a surface of the first light emitting layer on a side away from the first electrode is greater than 1200 Å.

14. The display panel according to claim 1, wherein the second light emitting layer, the third light emitting layer, the fourth light emitting layer, and the fifth light emitting layer emit blue light, and the first light emitting layer emits green light.

15. The display panel according to claim 14, wherein a surface of the first electrode facing the first light emitting layer serves as a reference surface, the second light emitting layer is located at a third antinode of the first standing wave, the third light emitting layer is located at a fourth antinode of the first standing wave, the fourth light emitting layer is located at a fifth antinode of the first standing wave, the fifth light emitting layer is located at a sixth antinode of the first standing wave, and the first light emitting layer is located at a second antinode of the second standing wave.

16. (canceled)

17. The display panel according to claim 1, wherein each of the four light emitting layers emitting light having the first wavelength among the first light emitting layer, the second light emitting layer, the third light emitting layer, the fourth light emitting layer and the fifth light emitting layer has a thickness in a range of 200 Å to 250 Å, and the light emitting layer emitting light having the second wavelength among the first light emitting layer, the second light emitting layer, the third light emitting layer, the fourth light emitting layer and the fifth light emitting layer has a thickness in a range of 300 Å to 350 Å.

18. The display panel according to claim 1, wherein each of the plurality of light emitting devices further comprises a first charge generating layer between the first light emitting layer and the second light emitting layer, a second charge generating layer between the second light emitting layer and the third light emitting layer, a third charge generating layer between the third light emitting layer and the fourth light emitting layer, and a fourth charge generating layer between the fourth light emitting layer and the fifth light emitting layer.

19. The display panel according to claim 1, wherein at least one light emitting layer in the plurality of light emitting devices comprises one or two layers of a hole injection layer and a hole transport layer which are on a side close to the first electrode, and one or two layers of an electron transport layer and an electron injection layer away from the first electrode.

20. The display panel according to claim 1, further comprising a wavelength conversion layer on a side of the second electrode away from the first electrode, wherein a material of the wavelength conversion layer comprises quantum dots.

21. A display apparatus, comprising the display panel according to claim 1.
